(19) United States
(12) Patent Application Publication
(10) Pub. No.: US 2009/0140293 A1
(43) Pub. Date: Jun. 4, 2009

(54) HETEROSTRUCTURE DEVICE AND ASSOCIATED METHOD

(75) Inventors: Alexei Vertiatchikh, Schenectady, NY (US); Kevin Sean Matocha, Rexford, NY (US); Peter Micah Sandvik, Clifton Park, NY (US); Vinayak Tilak, Niskayuna, NY (US); Siddharth Rajan, Goleta, CA (US); Ho-Young Cha, Seoul (KR)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, SCHENECTADY, NY (US)

(21) Appl. No.: 11/946,959

(22) Filed: Nov. 29, 2007

(51) Int. Cl. H01L 29/778

(52) U.S. Cl. 257/192; 257/E29.246

(57) ABSTRACT

A heterostructure device or article includes a carrier transport layer, a back channel layer and a barrier layer. The carrier transport layer has a first surface and a second surface opposing to the first surface. The back channel layer is secured to the first surface of the carrier transport layer and the barrier layer is secured to the second surface of the carrier transport layer. Each of the carrier transport layer, the back channel layer and the barrier layer comprises an aluminum gallium nitride alloy. The article further includes a 2D electron gas at an interface of the second surface of the carrier transport layer and a surface of the barrier layer. The 2D electron gas is defined by a bandgap differential at an interface, which allows for electron mobility. A system includes a heterostructure field effect transistor that includes the article.

### TECHNICAL FIELD

The invention includes embodiments that relate to a semiconductor heterostructure device. The invention includes embodiments that relate to a method of making and/or using the power semiconductor device.

### DISCUSSION OF RELATED ART

A semiconductor material for high power applications may need good thermal properties, high breakdown voltage, chemical inertness, mechanical stability and the ability to be fabricated as either a unipolar device or a bipolar device. Some currently available semiconductor materials for use as a power device may include silicon or gallium arsenide.

A field-effect transistor (FET) may rely on an electric field to control the conductivity of a “channel” that is defined in the semiconductor material. A FET, like all transistors, may be thought of as a voltage-controlled current source. Some FETs may use a single-crystal semiconductor wafer as the channel, or active region. A terminal in a FET may be one of a gate, a drain, or a source. The voltage applied between gate and source terminals may modulate the current between the source and the drain.

A FET that has two or more heterogeneous materials is a heterostructure field effect transistor (HFET), and may be a HEMT (High Electron Mobility Transistor). A HFET, or a HEMT, may be a field effect transistor with a junction between two materials as the channel, where the materials have differing band gaps (i.e., a heterojunction) relative to each other. The junction may create a thin layer where the Fermi energy level is above the conduction band, giving the channel very high electron mobility and leading to low on-state resistance for the channel. This thin layer may be referred to as a two-dimensional electron gas (2DEG). As with other types of FETs, a voltage applied to the gate alters the conductivity of the thin layer. Current commercial HFETs are normally-on, that is, the HFET conducts current even in absence of any potential applied between the gate and the source electrode. Such HFETs may not be practical or desirable in switching devices, such as inverters or converters.

It may be desirable to have a normally-off HFET with high threshold voltage and with high channel charge density. It may be desirable to have a switching device with properties that differ from the properties of available devices.

### BRIEF DESCRIPTION

In accordance with an embodiment of the invention, an article is provided that includes a carrier transport layer, a back channel layer and a barrier layer. The carrier transport layer has a first surface and a second surface opposing to the first surface. The back channel layer is secured to the first surface of the carrier transport layer and the barrier layer is secured to the second surface of the carrier transport layer. Each of the carrier transport layer, the back channel layer and the barrier layer comprises an aluminum gallium nitride alloy. The article further includes a 2D electron gas at an interface of the second surface of the carrier transport layer and a surface of the barrier layer. The 2D electron gas is defined by a bandgap differential at an interface allowing electron mobility. In one embodiment, a system is provided that includes a heterostructure field effect transistor that includes the article.

In accordance with an embodiment of the invention, a method of making an article is provided. The method includes depleting a 2D electron gas interface. In this embodiment, a barrier layer and a carrier transport layer in a semiconductor device define the 2D electron gas. The method includes inducing a negative electric charge to the carrier transport layer from a back channel layer. The back channel layer is secured to a first surface of the carrier transport layer and the barrier layer is secured to a second surface of the carrier transport layer opposite to the first surface. The method further includes providing a positive threshold voltage to create a normally-off device.

A heterostructure device is provided in one embodiment of the invention. The device includes a back channel layer comprising AlₓGa₁₋ₓN, a carrier transport layer comprising Al_{y}Ga_{1-y}N and a barrier layer comprising Al_{z}Ga_{1-z}N. The carrier transport layer has a first surface and a second surface opposing to the first surface. The back channel layer is secured to the first surface of the carrier transport layer and the barrier layer is secured to the second surface of the carrier transport layer. The device is normally-off so that there is no current flow through the carrier transport layer, that is, there is no 2D electron gas formed at the interface, if there is no electric potential applied to the barrier layer.

### BRIEF DISCUSSION OF DRAWINGS

Like numbers represent like parts throughout the drawings, wherein:

FIG. 1 is a schematic view of an article according to an embodiment of the invention.

FIG. 2 is a graph showing a relationship between an aluminum concentration of a back channel layer and a threshold voltage of the article according to one embodiment of the invention.

FIG. 3 is a graph showing a relationship between a thickness of the barrier layer and a threshold voltage of the article according to one embodiment of the invention.

FIG. 4 is a graph showing a relationship between a negative electric charge of a dielectric layer and a threshold voltage of the article according to one embodiment of the invention.

FIG. 5 is a schematic view of an article according to an embodiment of the invention.

FIG. 6 is a schematic view of an article according to an embodiment of the invention.

### DETAILED DESCRIPTION

The invention includes embodiments that relate to a semiconductor device, such as a heterostructure device. The invention includes embodiments that relate to a method of making and/or using the device as a power semiconductor device.

Approximating language, as used herein throughout the specification and claims, may be applied to modify any quantitative representation that could permissibly vary without resulting in a change in the basic function to which it may be about related. Accordingly, a value modified by a term such as “about” is not limited to the precise value specified. In some instances, the approximating language may correspond to the precision of an instrument for measuring the value. As used herein, the term “secured to” or “disposed over” or “deposited over” or “disposed between” refers to both direct contact with and to indirect contact by having intervening layers therebetween.

According to one embodiment, an article is provided that includes a carrier transport layer, a back channel layer, and a barrier layer. The carrier transport layer has a first surface and a second surface opposing to the first surface. The back channel layer is secured to the first surface of the carrier transport layer and the barrier layer is secured to the second surface of the carrier transport layer. Furthermore, the article defines a 2D electron gas (2DEG) that forms at an interface of the second surface of the carrier transport layer and a surface of the barrier layer. The 2D electron gas is formed by bandgap differential of the carrier transport layer and the barrier layer. The ‘2D electron gas’ is a planar region or channel of high charge and high mobility electrons and may be responsible for charge flow in a device. In nitride-based devices, this charge flow effect may be enhanced by a polarization effect produced in the barrier layer. In one embodiment, the back channel layer is a buffer layer.

The presence of the back channel layer may affect the 2D electron gas density and polarization effect. In one embodiment, the back channel layer may induce negative electric charge to the carrier transport layer, which may deplete a negative charge within the layer of the 2D electron gas. In other words, the induced negative electric charge may repel the actual negative charge within the 2D electron gas and may prevent accumulation of negative charges (electrons).

In one embodiment, a positive polarization sheet charge may exist at the interface of the second surface of the carrier transport layer and the barrier layer and a negative polarization sheet charge may exist at interface of the first surface of the carrier transport layer and the back channel layer. The negative polarization sheet charge may offset the effect of the positive polarization sheet charge and thus may deplete the 2D electron gas.

The depletion of the 2D electron gas due to the presence of back channel layer may raise the conduction band from Fermi level. This may provide a positive threshold voltage to create a normally-off device or an enhancement mode device. “Threshold voltage” is a minimum gate source voltage required for conduction of source-drain current for a normally-off. Normally-off indicates that a circuit is open from one predetermined point to another unless an external stimulus is provided to close the circuit and turn the device “on”. For example, a voltage less than the threshold voltage applied to a gate electrode may not allow electrical communication from a source electrode to a drain electrode. As used herein, the term “normally-off” refers to a device in which negligible or no current flows in the absence of an applied electrical potential to a proximate gate electrode.

The 2D electron gas density generated by the bandgap differential and the polarization effect may depend on alloy compositions and thicknesses of the layers. Each of the carrier transport layer, the back channel layer and the barrier layer may include an aluminum gallium nitride (AlGaN) alloy having different concentrations of aluminum. The back channel layer may have composition AlₓGa₁₋ₓN having a concentration ‘x’ of aluminum, the carrier transport layer may have composition Al_{y}Ga_{1-y}N having a concentration ‘y’ of aluminum and the barrier layer may have composition Al_{z}Ga_{1-z}N having a concentration ‘z’ of aluminum.

As value of aluminum concentration increases, the bandgap of aluminum gallium nitride alloy increases. In one embodiment, the aluminum concentration x of the back channel layer may be less than the aluminum concentration z of the barrier layer and may be higher than the aluminum concentration y of the carrier transport layer. Also, the value of z may be higher than the value of y to have larger bandgap of the barrier layer than the carrier transport layer to generate 2D electron gas. The values of the concentrations x and z may be controlled so that the threshold voltage can be controlled. In an another embodiment, the concentrations x, y and z have a ratio defined by 0≦y≦x<z≦1.

In one embodiment, the polarization effect may not change significantly with the aluminum concentrations of the AlGaN layers. However, a workfunction of an AlGaN alloy may increase with an increase in aluminum concentration in the layer. Higher workfunctions of the layers may lead to higher barrier height, and in turn provide higher threshold voltage. Higher aluminum concentration in an AlGaN layer may affect the difficulty in the creation of an ion-implanted region and/or in the formation of an ohmic contact. It may be necessary for practicability to balance aluminum concentration versus other properties of the device. The layer thicknesses may affect device size, robustness, yield and performance. It may be necessary for practicability to balance layer thickness versus other properties of the device.

The concentration “x” may have value that is less than about 0.5 mole percent. In one embodiment, the concentration x may be in a range of from about 0.01 mole percent to about 0.04 mole percent, from about 0.04 mole percent to about 0.08 mole percent, from about 0.08 mole percent to about 0.1 mole percent, from about 0.1 mole percent to about 0.2 mole percent, from about 0.2 mole percent to about 0.3 mole percent, from about 0.3 mole percent to about 0.4 mole percent, or from about 0.4 mole percent to about 0.5 mole percent.

The concentration “y” may have value that is greater than about 0.01 mole percent. In one embodiment, the concentration y may be in a range of from about 0.01 mole percent to about 0.02 mole percent, from about 0.02 mole percent to about 0.03 mole percent, from about 0.03 mole percent to about 0.04 mole percent, from about 0.04 mole percent to about 0.05 mole percent, from about 0.05 mole percent to about 0.06 mole percent, from about 0.06 mole percent to about 0.07 mole percent, from about 0.07 mole percent to about 0.08 mole percent, from about 0.08 mole percent to about 0.09 mole percent, or from about 0.09 mole percent to about 0.1 mole percent, or from about 0.1 mole percent to about 0.2 mole percent.

The concentration “z” may have value less than about 0.5 mole percent. In one embodiment, the concentration z may be in a range of from about 0.01 mole percent to about 0.04 mole percent, from about 0.04 mole percent to about 0.08 mole percent, from about 0.08 mole percent to about 0.1 mole percent, from about 0.1 mole percent to about 0.2 mole percent, from about 0.2 mole percent to about 0.3 mole percent, from about 0.3 mole percent to about 0.4 mole percent, or from about 0.4 mole percent to about 0.5 mole percent.

Each of the carrier transport layer, the back channel layer and the barrier layer may have thicknesses such that to provide the positive threshold voltage. In one embodiment, the thickness of the back channel layer may be greater than either of the thickness of the barrier layer or the thickness of the carrier transport layer. The thickness of the carrier transport layer may be less than about 300 Angstroms. In one embodiment, the thickness of the carrier transport layer may be in a range of from about 10 Angstroms to about 50 Angstroms, from about 50 Angstroms to about 100 Angstroms, from about 100 Angstroms to about 150 Angstroms, from about 150 Angstroms to about 200 Angstroms, from about 200 Angstroms to about 250 Angstroms, or from about 250 Angstroms to about 300 Angstroms.

The thickness of the back channel layer may be less than about 400 micrometers. In one embodiment, the thickness of the back channel layer may be in a range of from about 10 Angstroms to about 100 Angstroms, from about 100 Angstroms to about 500 Angstroms, or from about 500 Angstroms to about 1 micrometer. In one embodiment, the back channel layer thickness may be in a range of from about 1 micrometer to about 10 micrometers, from about 10 micrometers to about 100 micrometers, from about 100 micrometers to about 200 micrometers, from about 200 micrometers to about 300 micrometers, or from about 300 micrometers to about 400 micrometers.

The thickness of the barrier layer may be less than about 300 Angstroms. In one embodiment, the thickness of the barrier layer may be in a range of from about 10 Angstroms to about 50 Angstroms, from about 50 Angstroms to about 100 Angstroms, from about 100 Angstroms to about 150 Angstroms, from about 150 Angstroms to about 200 Angstroms, from about 200 Angstroms to about 250 Angstroms, or from about 250 Angstroms to about 300 Angstroms.

The article may be formed on, secured to, or otherwise include a substrate. The substrate may provide mechanical support to the device. In one embodiment, the substrate may be electrically semi insulating. In another embodiment, the substrate may be electrically conducting. A suitable substrate may contain one or more metal or metalloid, such as silicon, aluminum, or gallium. These substrates may be oxides, carbides, nitrides, silicides, aluminides, and the like. Suitable materials for the substrate may include silicon carbide, aluminum oxide, aluminum nitride, gallium nitride, lithium aluminum oxide, or lithium gallium oxide. In one embodiment, the aluminum oxide is in the form of sapphire.

The substrate may be coupled to a surface of the back channel layer that is opposite to the surface that is secured to the carrier transport layer. Accordingly, the lattice constant of the substrate and the back channel layer may be matched to reduce the number of surface defects. Surface defects may include micro-cracks or threading dislocations, which may form at an interface with the substrate.

A dielectric layer may be deposited in contact to a portion of the barrier layer on a surface opposite to the carrier transport layer. The dielectric layer may insulate a gate electrode from the barrier layer. Insulation may reduce or prevent any leakage currents from a gate electrode. Insulation may facilitate application of higher potentials at a gate electrode while preventing adverse effects, such as leakage current, which may otherwise be produced upon application of high potentials. For example, the dielectric layer reduces or prevents leakage currents upon application of potential above 1 volt. Furthermore, the dielectric layer may have an electric charge. In one embodiment, the electric charge produced at a surface of the dielectric layer may be negative to generate a negative electric field. The negative electric field may terminate an electric field exists at the surface of the barrier layer opposite to the surface secured to the carrier transport layer and may enhance the 2D electron gas density. Thus, this effect may increase the threshold voltage to a value higher than the threshold voltage without the presence of the dielectric layer. In another embodiment, the electric charge may be positive and creates a positive electric field. The positive electric field creates opposite effect and may reduce the threshold voltage. The electric charge produced within the dielectric layer may depend on dielectric material and deposition conditions.

The electric charge at a surface of the dielectric layer may be controlled by thickness of the dielectric layer and deposition temperature. In one embodiment, the dielectric layer may be thick enough to insulate a gate electrode from the barrier layer to prevent any leakage currents at a gate electrode while maintaining low on-resistance. The dielectric layer may be thick enough to prevent tunneling of electrons or holes between a gate electrode and the barrier layer. The tunneling may increase leakage currents at a gate electrode. The thickness of the dielectric layer may be more than about 10 Angstroms. The thickness of the dielectric layer may be in a range of from about 10 Angstroms to about 100 Angstroms, from about 100 Angstroms to about 200 Angstroms, from about 200 Angstroms to about 300 Angstroms, from about 300 Angstroms to about 400 Angstroms, from about 400 Angstroms to about 500 Angstroms, from about 500 Angstroms to about 600 Angstroms, from about 600 Angstroms to about 700 Angstroms, from about 700 Angstroms to about 800 Angstroms, from about 800 Angstroms to about 900 Angstroms, or from about 900 Angstroms to about 1000 Angstroms.

The deposition temperature of the dielectric layer may be more than about 300 degrees Centigrade. The deposition temperature may be in a range of from about 300 degrees Centigrade to about 500 degrees Centigrade, from about 500 degrees Centigrade to about 700 degrees Centigrade, from about 700 degrees Centigrade to about 900 degrees Centigrade, from about 900 degrees Centigrade to about 1100 degrees Centigrade, from about 1100 degrees Centigrade to about 1300 degrees Centigrade, or from about 1300 degrees Centigrade to about 1500 degrees Centigrade.

Suitable materials for the dielectric layer may include one or more of silicon nitride, silicon dioxide, hafnium oxide, phosphosilicate glass, or borophosphosilicate glass. In one embodiment, the dielectric layer may be deposited using Low Pressure Chemical Vapor Deposition (LPCVD) method or metal organic chemical vapor deposition (MOCVD) method.

The article may further include a gate electrode, a source electrode, and a drain electrode. The gate electrode, the drain electrode and the source electrode may be formed on the surface of the barrier layer. The electrodes may be coupled to the device to provide Ohmic contacts. The electrodes may be formed using standard deposition and photolithographic techniques.

The gate electrode may control a current flowing between the source electrode and the drain electrode. The current may not flow between the source electrode and the drain electrode until a voltage is applied to the gate electrode. Suitable materials for the gate electrode may include nickel, aluminum, copper, palladium, palladium silicon, platinum, or gold, or an alloy of the foregoing.

In one embodiment, the article may further include a plurality of surface regions. The plurality of surface regions may exist into the barrier layer. The plurality of surface regions may have a first surface region and a second surface region. The surface regions may be formed by ion implantation. The first surface region may exist underneath the source electrode and the second surface region may exist underneath the drain electrode. The first and second surface regions may provide ohmic contacts to the device. A third surface region may separate the first and second surface regions. The third surface region may exist below the gate electrode. The third surface region may not be ion-implanted.

In one embodiment, a recess cut may be formed into the barrier layer below the gate electrode. The recess may divide the 2D electron gas into a first portion and a second portion. The first portion may be reversibly electrically isolated from the second portion by the recess. Application of a voltage potential to gate electrode, disposed in or near the recess may allow electrical communication of the first portion to the second portion.

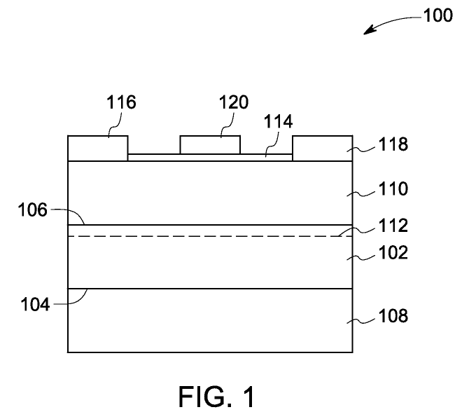

An article 100 that is a normally-off heterostructure field effect transistor (HFET) in accordance with an embodiment is shown in FIG. 1. The article includes a carrier transport layer 102. The carrier transport layer has a first surface 104 and a second surface 106 opposing to the first surface. The article further includes a back channel layer 108 and a barrier layer 110. The back channel layer is secured to the first surface of the carrier transport layer and the barrier layer is secured to the second surface of the carrier transport layer. Each of the carrier transport layer, the back channel layer and the barrier layer may include an aluminum gallium nitride (AlGaN) alloy having different concentrations of aluminum. The back channel layer may have composition AlₓGa₁₋ₓN having a concentration ‘x’ of aluminum, the carrier transport layer may have composition Al_{y}Ga_{1-y}N having a concentration ‘y’ of aluminum and the barrier layer may have composition Al_{y}Ga_{1-y}N having a concentration ‘z’ of aluminum. Furthermore, a 2D electron gas 112 that forms at an interface of the second surface of the carrier transport layer and a surface of the barrier layer.

An optional dielectric layer 114 may be present on an outward facing surface of the barrier layer. If present, the dielectric layer contacts a portion of the barrier layer 110 on a surface opposite to the carrier transport layer 102. The dielectric layer includes a negative electric charge, which further increases the threshold voltage of the HFET. Controlling thickness of the dielectric layer can optimize the negative electric charge. The normally off HFET can further include a source electrode 116, a drain electrode 118, and a gate electrode 120.

Little to no electric current flows between the source electrode and the drain electrode through the 2D electron gas interface until a sufficiently high electric potential is applied to the gate electrode. As illustrated in FIG. 1, in the presence of applied potential to the gate electrode 120, the 2D electron gas 112 may extend and form a continuous electrically conductive channel between the source electrode and the drain electrode. This is reversible electrical coupling of the source electrode and the drain electrode. By way of contrast, an off-mode of operation (not shown) would have an electrical discontinuity from the source electrode to the drain electrode via the 2D electron gas.

The 2D electron gas density depends on the thickness and aluminum concentration of the barrier layer and the carrier transport layer. The thickness and aluminum concentration of the back channel layer may be such that to provide a negative polarization sheet charge to deplete the 2D electron gas. This effect raises the conduction band from Fermi level and thus provides a positive threshold voltage (normally off device). The increase in the threshold voltage (Vₜₕ) of the HFET device due to the presence of the back channel layer may be calculated by a term

$$\frac{q σ}{ɛ} t ,$$

where σ is the negative polarization sheet charge at the interface of the back channel layer and the first surface of the carrier transport layer, t is the thickness of the barrier layer and ∈ is dielectric constant.

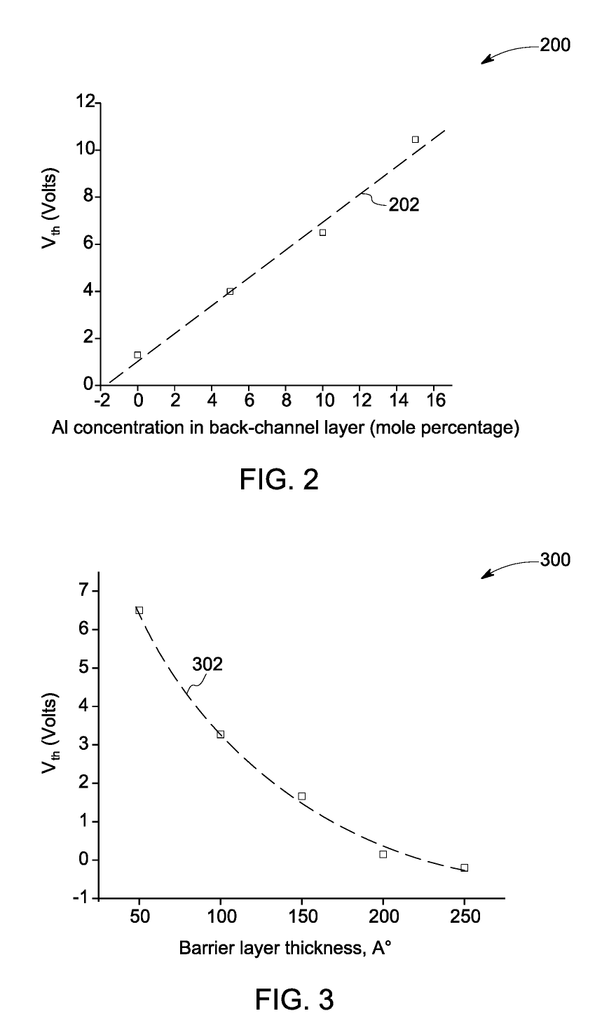

The dependence of threshold voltage (Vₜₕ) on aluminum concentration of the back channel layer and on the thickness of the barrier layer are indicated in the graphs of FIG. 2 and FIG. 3. FIG. 2 includes a graph 200 that indicates a relationship of threshold voltage (Vₜₕ) with aluminum concentration ‘x’ of the back channel layer. Aluminum concentration ‘x’ in moles percent is represented on x-axis while threshold voltage is represented on y-axis. The graph shows a straight line indicated by 202. The threshold voltage dependence takes a positive value and increases with aluminum concentration x of the back channel layer.

FIG. 3 includes a graph 300 that indicates a relationship between threshold voltage and barrier layer thickness. Thickness of the barrier layer is represented on x-axis and threshold voltage is represented on y-axis. The curve 302 indicates that an increase in the threshold voltage correlates to a decrease in barrier layer thickness. Thus, by controlling barrier layer thickness, and the aluminum concentration of the back channel layer, the HFET threshold voltage of the can be controlled.

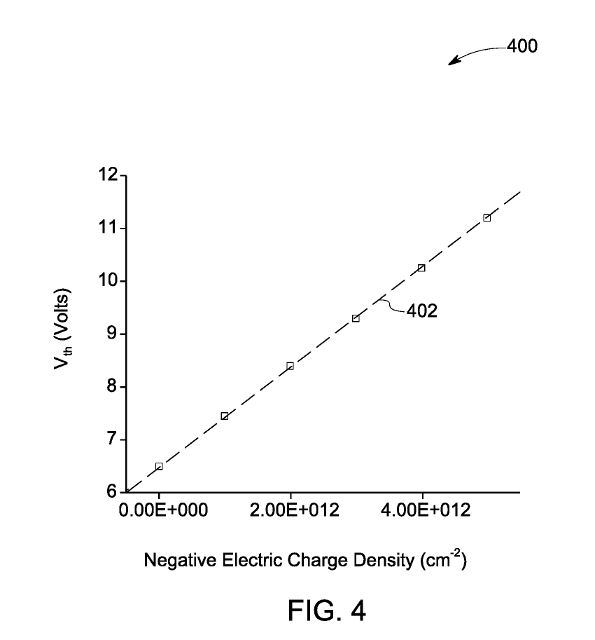

The effect of the electric charge on the surface of the dielectric layer, according to one embodiment, is shown in FIG. 4. FIG. 4 includes a graph indicated by reference number 400. The graph axes include threshold voltage (Vₜₕ) and the electric charge of the dielectric layer. The electric charge per square centimeter is represented on x-axis, and threshold voltage is represented on y-axis. The graph shows a linear increase indicated by 402. The more negative electric charge induced on the surface of the dielectric layer the higher will be the threshold voltage of the HFET device.

A suitable HFET may have an On-Resistance that is greater than about 0.1 milliohm per centimeter squared. In one embodiment, the On-Resistance of the HFET may be in a range of from about 0.1 milliohm per centimeter square to about 1 milliohm per centimeter square, from about 1 milliohm per centimeter square to about 10 milliohm per centimeter square, from about 10 milliohm per centimeter square to about 50 milliohm per centimeter square, or from about 50 milliohm per centimeter square to about 100 milliohm per centimeter square.

The HFET may have a blocking voltage that is more than about 100 volts. In one embodiment, the blocking voltage of the HFET may be in a range of from about 100 volts to about 1000 volts, from about 1000 volts to about 5000 volts, from about 5000 volts to about 10,000 volts, from about 10,000 volts to about 20,000 volts, from about 20,000 volts to about 30,000 volts, from about 30,000 volts to about 40,000 volts, or from about 40,000 volts to about 50,000 volts.

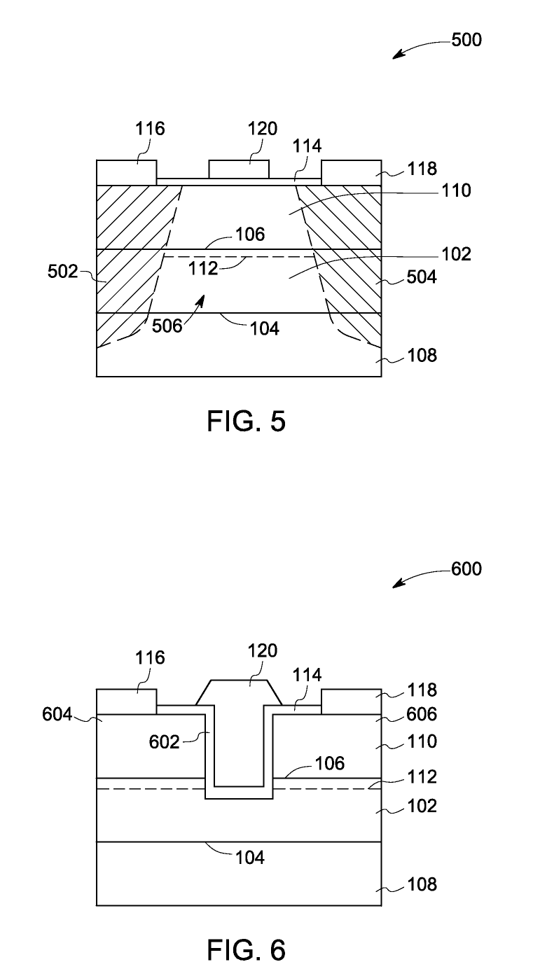

FIG. 5 illustrates a normally-off, ion-implanted HFET 500. The HFET 500 may have a plurality of surface regions defined on a surface of the barrier layer. The plurality of surface regions may include a first surface region 502 and a second surface region 504, each region spaced from each other and formed by ion implantation. The first surface region is coupled to the source electrode 116 and the second surface region is coupled to the drain electrode 118. A third surface region 506 spatially separates the first surface region from the second surface region. The third surface region may exist adjacent to, or below, the gate electrode 120.

A normally off HFET 600 configured with a recess structure is shown in FIG. 6. Inner surfaces of the HFET layers are etched to define a volume or recess 602. The recess may be etched into the barrier layer below the gate electrode 120 by removing a portion of the barrier layer. The recess may divide the 2D electron gas into a first portion 604 and a second portion 606. The first portion may be reversibly electrically isolated from the second portion by the recess. Application of a voltage potential to gate electrode 120 may allow electrical communication of the first portion to the second portion.

Normally-off devices may be desirable for high power applications, such as high power, high temperature and high frequency applications. For switching devices, such as inverters or converters, a normally-off type device having a low-On-resistance may be desirable, because of their low leakage current. The low leakage currents may result in improved efficiency and increased device reliability. Embodiments of the invention may be useful in, for example, a power diode, thyristor, power MOSFET, power MISFET, or an IGBT (insulated gate bipolar transistor).

### EXAMPLES

### Example 1

### Forming Normally-Off Heterostructure Field Effect Transistors

Two normally-off aluminum gallium nitride based heterostructure field effect transistors (HFET) are formed. In both structures, a back channel layer is formed from a 1-micrometer thick epilayer having a composition of Al_{0.1}Ga_{0.9}N. The back channel layer is formed on a sapphire substrate. A 30-Angstrom thick carrier transport layer is epitaxially grown on the back channel layer. The carrier transport layer includes Al_{0.01}Ga_{0.99}N. A 50-Angstrom thick barrier layer is epitaxially grown on the carrier transport layer. The barrier layer includes Al_{0.15}Ga_{0.85}N. A 200-Angstrom thick dielectric layer is formed on a portion of the barrier layer. The dielectric layer includes silicon dioxide and is deposited by low-pressure chemical vapor deposition (LPCVD) at 300 degrees Centigrade.

The first of the two structures has source and drain Ohmic contact pads formed by using an ion implantation method. The other of the two structures has a recess formed in the barrier layer forming two physically separated and electrically isolatable Ohmic contact pads.

Next, metallization deposits a source, drain and gate electrode. A 2D electron gas forms at the carrier transport and barrier layer interface. The 2DEG is depleted due to the presence of the back channel layer. The device provides a positive threshold voltage of 6.5 volts to operate in a normally-off mode.

### Example 2

### Effect of Thickness and Concentration on Threshold Voltage

Two sets of 3 samples are created in a manner similar to the devices formed in Example 1; except that the samples have the values listed in Table 1. The values for each of the first set and the second set are the same as each other except that the first set (1A, 2A, 3A) involves ion implantation for the contact pads, and the second set (1B, 2B, 3B) involves reversibly electrically isolating the contact pads by a physical removal of material to define a recess.

As indicated by data, controlling the thickness and aluminum concentrations of the layers control the threshold voltage. The aluminum concentration ‘y’ of the carrier transport layer is less than the aluminum concentration ‘z’ of the barrier layer to lead an increase in the density of 2D electron gas. However, by controlling the concentration of the back channel layer less than the aluminum concentration of the barrier layer provides positive threshold voltage. While thickness of the back channel layer is maintained larger than the carrier transport layer and the barrier layer.

The data as indicated in Table 1, also shows effect of deposition temperature and thickness of the dielectric layer. By depositing the dielectric layer at higher deposition temperature, while controlling the thickness, further enhances the threshold voltage by creating or providing more electric charge at the surface of the dielectric layer.

TABLE 1
Samples 1A, 1B, 2A, 2B, 3A and 3B properties.

| | Back Channel Layer | | Carrier Transport Layer | | Barrier Layer | | Dielectric Layer | | |
|---|---|---|---|---|---|---|---|---|---|
| | | Aluminum | | Aluminum | | Aluminum | | Deposition | Threshold |
| | Thickness | concentration | Thickness | concentration | Thickness | concentration | Thickness | Temperature | Voltage |
| Sample # | (Micrometer) | ‘x’ | (Angstrom) | ‘y’ | (Angstrom) | ‘z’ | (Angstrom) | (° C.) | (Volts) |
| 1A | 1 | 0.1 | 30 | 0.01 | 50 | 0.15 | 200 | 300 | 6.5 |
| 2A | 1 | 0.15 | 30 | 0.05 | 50 | 0.2 | 200 | 900 | 10 |
| 3A | 1 | 0.2 | 50 | 0.1 | 80 | 0.25 | 300 | 500 | 6 |
| 1B | 1 | 0.1 | 30 | 0.01 | 50 | 0.15 | 200 | 300 | 6.5 |
| 2B | 1 | 0.15 | 30 | 0.05 | 50 | 0.2 | 200 | 900 | 10 |
| 3B | 1 | 0.2 | 50 | 0.1 | 80 | 0.25 | 300 | 500 | 6 |

The embodiments described herein are examples of compositions, structures, systems and methods having elements corresponding to the elements of the invention recited in the claims. This written description may enable those of ordinary skill in the art to make and use embodiments having alternative elements that likewise correspond to the elements of the invention recited in the claims. The scope of the invention thus includes compositions, structures, systems and methods that do not differ from the literal language of the claims, and further includes other structures, systems and methods with insubstantial differences from the literal language of the claims. While only certain features and embodiments have been illustrated and described herein, many modifications and changes may occur to one of ordinary skill in the relevant art. The appended claims cover all such modifications and changes.

1. An article, comprising:
a carrier transport layer;
a back channel layer secured to a first surface of the carrier transport layer; and
a barrier layer secured to a second surface of the carrier transport layer opposite the first surface, and
each of the carrier transport layer, the back channel layer and the barrier layer, comprise an aluminum gallium nitride alloy, a 2D electron gas is defined by a bandgap differential at an interface of the second surface of the carrier transport layer and a surface of the barrier layer.

2. The article as defined in claim 1, wherein the back channel layer induces negative electric charge to the carrier transport layer, and depletes negative charge within two dimensional electron gas, and provides a positive threshold voltage to create a normally-off device.

3. The article as defined in claim 1, wherein the back channel layer has a concentration ‘x’ of aluminum, the carrier transport layer has a concentration ‘y’ of aluminum and the barrier layer has a concentration ‘z’ of aluminum.

4. The article as defined in claim 2, wherein the concentration of aluminum x of the back channel layer is less than the concentration of aluminum ‘z’ of the barrier layer.

5. The article as defined in claim 2, wherein the concentrations ‘x’, ‘y’ and ‘z’ have a ratio defined by 0≦y≦x<z≦1.

6. The article as defined in claim 1, wherein a thickness of the back channel layer is more than either of a thickness of the barrier layer or a thickness of the carrier transport layer.

7. The article as defined in claim 1, further comprising a substrate, and the substrate comprises silicon, aluminum, or gallium.

8. The article as defined in claim 7, wherein the substrate comprises a material selected from the group consisting of silicon carbide; lithium aluminum oxide; aluminum nitride; gallium nitride; and aluminum oxide or sapphire.

9. The article as defined in claim 1, wherein the substrate that is electrically semi insulating.

10. The article as defined in claim 1, further comprises a substrate that is an electrically conductive substrate.

11. The article as defined in claim 1, further comprising a dielectric layer contacting at least a portion of the barrier layer on a surface opposite to the carrier transport layer, and the dielectric layer comprises silicon oxide, silicon nitride, hafnium oxide, phosphosilicate glass, or borophosphosilicate glass.

12. The article as defined in claim 11, wherein the dielectric layer comprises an electric charge and increases a threshold voltage of the article to a value higher than the threshold voltage would be without the presence of the dielectric layer.

13. The article as defined in claim 1, further comprising a gate electrode, a source electrode, and a drain electrode.

14. The article as defined in claim 1, further comprising a plurality of surface regions exist into the barrier layer wherein a first surface region and a second surface region formed by ion implantation, underneath the source electrode and the drain electrode, and separated by a third surface region between the first and second surface regions below the gate electrode.

15. The article as defined in claim 1, wherein a recess cut into the barrier layer divides the 2D electron gas into a first portion and a second portion, and the first portion is reversibly electrically isolated from the second portion by the recess, and application of a voltage potential to a gate electrode that is disposed in or near the recess allows electrical communication of the first portion to the second portion.

16. A heterostructure field effect transistor comprising an article as defined in claim 1.

17. The heterostructure field effect transistor as defined in claim 16, wherein an On-resistance for the transistor is in a range of from about 0.1 milliohms per centimeter square to about 100 milliohms per centimeter square.

18. The heterostructure field effect transistor as defined in claim 16, wherein a blocking voltage of the transistor is in a range of from about 100 volts to about 50000 volts.

19. A method, comprising:
depleting a 2D electron gas interface that is defined by a barrier layer and a carrier transport layer in a semiconductor device, wherein the depleting comprises inducing a negative electric charge in the carrier transport layer from the back channel layer, wherein the back channel layer is secured to a first surface of the carrier transport layer and the barrier layer is secured to a second surface of the carrier transport layer opposite the first surface; and
applying a voltage potential that is greater than a threshold voltage to a gate electrode to allow current to flow from a source electrode to a drain electrode, and to switch on a normally-off device.

20. The method as defined in claim 19, further comprising forming a recess in the barrier layer, depositing a dielectric layer on the barrier layer and depositing a gate electrode into the recess on the dielectric layer.

21. The method as defined in claim 19, further comprising implanting ions into the barrier layer in a first surface region and a second surface region, underneath a source electrode and a drain electrode, and separated by a third surface region between the first and second surface regions below a gate electrode, depositing a dielectric layer on the barrier layer and depositing the gate electrode in the third region.

22. A method as defined in claim 19, wherein each of the back channel layer, the carrier transport layer and the barrier layer comprise aluminum.

23. A heterostructure device, comprising:
a back channel layer comprising AlₓGa₁₋ₓN;
a carrier transport layer comprising Al_{y}Ga_{1-y}N; and
a barrier layer comprising Al_{z}Ga_{1-z}N,
wherein the back channel layer and the barrier layer secure to opposing surfaces of the carrier transport layer and the device is normally-off so that there is no current flow through the carrier transport layer at a 2D electron gas interface if there is no electric potential applied to the barrier layer.

24. The device as defined in claim 23, wherein the back channel layer has a concentration ‘x’ of aluminum, the carrier transport layer has a concentration ‘y’ of aluminum and the barrier layer has a concentration ‘z’ of aluminum.

25. The device as defined in claim 23, wherein the concentration of aluminum x of the back channel layer is less than the concentration of aluminum z of the barrier layer.
